(19) United States
(12) Patent Application Publication
(10) Pub. No.: US 2026/0065977 A1
(43) Pub. Date: Mar. 5, 2026

(54) Assertion of Word Line After Fully Pulling Down Bit Lines in Memory Circuits

(71) Applicant: Taiwan Semiconductor Manufacturing Company, Ltd., Hsinchu (TW)

(72) Inventors: Yumito Aoyagi, New Taipei City (TW); Makoto Yabuuchi, Hsinchu City (TW)

(73) Assignee: Taiwan Semiconductor Manufacturing Company, Ltd., Hsinchu (TW)

(21) Appl. No.: 18/819,336

(22) Filed: Aug. 29, 2024

(51) Int. Cl. G11C 11/418; G11C 11/412; G11C 11/419

(52) U.S. Cl. CPC G11C 11/418; G11C 11/412; G11C 11/419

(57) ABSTRACT

Memory devices, circuits, and a method of operating the same are disclosed. In one aspect, a memory device includes a memory cell coupled to a bit line and a word line. The memory device includes a first delay circuit configured to generate a first delay signal to activate a word line driver according upon the bit line of the memory cell transitioning to a logic low state. The memory device includes a second delay circuit configured to generate a second delay signal to deactivate the word line driver according to at least an amount of time to assert the word line coupled to the memory cell.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram of an example memory circuit including additional delay circuits to reduce contention during memory operations, in accordance with some embodiments.

FIG. 2 illustrates a diagram showing example waveforms of signals that can propagate through the memory circuit shown in FIG. 1 during memory operations, in accordance with some embodiments.

FIG. 3 illustrates a diagram of an example memory circuit showing read and write paths for delay to reduce contention during memory operations, in accordance with some embodiments.

FIG. 4 illustrates a diagram of an example tracking memory cell of the memory circuits described herein, in accordance with some embodiments.

FIG. 5 illustrates a diagram of example waveforms of signals that can propagate through the memory circuit shown in FIG. 3 during memory operations, in accordance with some embodiments.

FIG. 6 illustrates a diagram of example waveforms of signals that can propagate through the memory circuit shown in FIG. 3 involving signals for a write assistance circuit, in accordance with some embodiments.

FIG. 7 illustrates a diagram of an example memory circuit similar to the memory circuit shown in FIG. 3, implemented for multiple memory banks, in accordance with some embodiments.

FIG. 8 illustrates a diagram of example waveforms of signals that can propagate through the memory circuit shown in FIG. 7, in accordance with some embodiments.

FIG. 9 illustrates a flowchart of example method of operating an example memory circuit that implements delays to reduce contention during memory operations, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Memory circuits, include static random-access memory (SRAM) circuits, often includes arrays of memory cells that are selectively controlled to perform read and write operations. Such operations are synchronous, and one challenge to designing memory devices includes ensuring that circuit elements are activated with correct timing to avoid unnecessary delays and power consumption. In certain circumstances, activating multiple signals for write operations in conventional memory cells results in contention between components of a memory cell, reducing the effectiveness and performance of the write operation.

During a write operation in a conventional memory cell, a bit line (BL) coupled to the memory cell carries the data to be written (e.g., by its voltage level), and a word line (WL) coupled to the memory cell activates the access transistors of the memory cell, allowing the voltage signal carried on the bit lines to be written to the memory cell. When performing write operations in conventional memory cells, a memory controller drives the BL to the desired voltage level and activates the WL almost simultaneously. For example, when writing a binary “0” to the memory cell, the BL of the memory cell is pulled down (e.g., to a logic zero or ground voltage), and the WL of the memory cell is asserted to activate the access transistors, allowing BL to affect the storage node in the memory cell.

However, contention can occur when there are opposing forces trying to influence the state of the memory cell. Furthering the above example, if the memory cell stores a value of “1”, a pull-up resistor is actively driving the storage node of to a logic high state (e.g., about the supply voltage of the memory cell), while the memory controller pulls the bit line down to a logic low state (e.g., the ground voltage). As simultaneously asserting the word line connects the bit line to the storage node through the access transistor of the memory cell, the storage node of the storage node experiences strong contention. This contention can degrade the write margin of the memory cells, thereby increasing the power requirement to write to the memory cell in the worst case, increasing the time to write to the memory cell (e.g., as a wait time is required to resolve the contention), and introducing a possibility of write failure to the memory cell.

The present disclosure provides various techniques for implementing memory circuits having additional delay circuits to reduce contention during memory operations. Rather than asserting bit lines and word lines of memory circuits simultaneously, resulting in contention during memory write operations, the techniques described herein delay assertion of the word line after bit lines have been pulled down. These techniques reduce the overall contention at the storage nodes of memory cells when writing data to memory cells, thereby reducing required power consumption, increasing write speeds, and reducing instances of write failures.

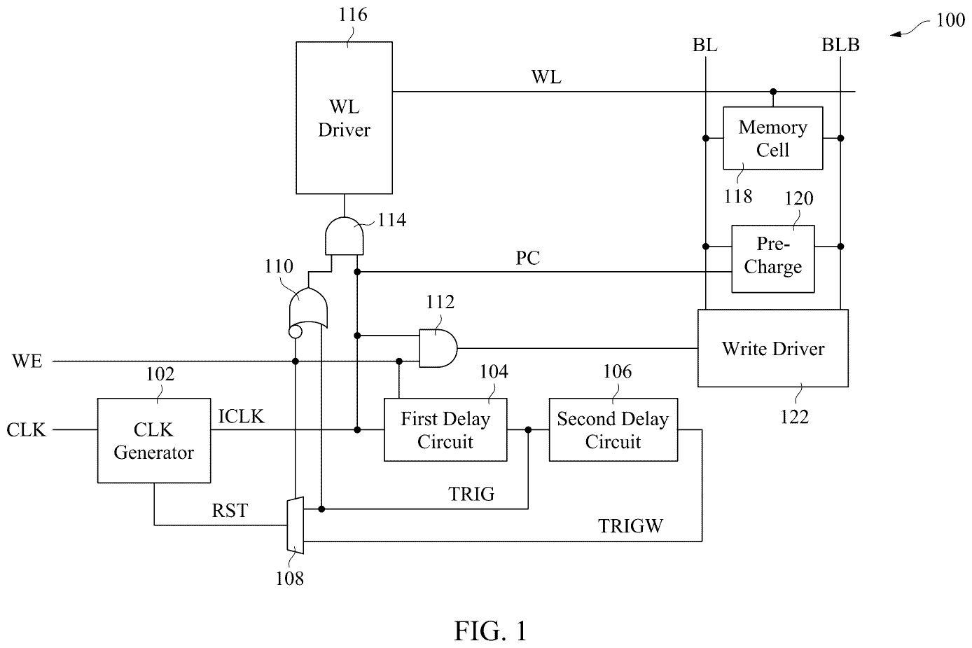

FIG. 1 illustrates a diagram of an example memory circuit 100 having delay circuits to reduce contention during memory operations, in accordance with some embodiments. The memory circuit 100 can be included in any type of memory device or integrated circuit (IC) device. In at least one embodiment, a memory device is an individual IC device. In some embodiments, a memory device is included as a part of a larger IC device which comprises circuitry other than the memory device for other functionalities.

Each of the components shown in the memory circuit 100 may receive power from one or more voltage sources. The memory circuit 100 may include one or more logic gates and sub-circuits, each of which may be constructed from one or more logic gates. Logic gates are electronic devices that perform logical operations on one or more input signals to produce a single output signal. Various embodiments of the circuits and logic gates that implement the memory circuit 100 may include various transistors. The transistors described herein may have a certain type (n-type or p-type), but embodiments are not limited thereto. The transistors can be any suitable type of transistor including, but not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

It should be understood that although the memory circuit 100 shown in FIG. 1 can be a portion of a larger memory circuit, including any number of pairs of bit lines BL and BLB or word lines WL, which may be addressed by corresponding memory cell selection circuitry. Likewise, although not shown here for visual clarity, various additional circuitry may be included to address (e.g., select) various portions of the memory cells or to perform different memory operations, such write operations or read operations, among others.

The memory circuit 100 is shown as including at least one memory cell 118 positioned between a pair of bit lines BL and BLB. The memory cell 118 can be any type of memory device capable of storing at least one bit of memory data, including but not limited to an SRAM cell or a dynamic random-access memory (DRAM) cell, among others. The bit lines BL and BLB, and the memory cell 118 therebetween, can be included as a portion of a column of a memory array, in some implementations. As shown, a pre-charge circuit 120 is coupled between the bit lines BL and BLB. The pre-charge circuit 120 can include any type of circuitry to charge the bit lines BL and BLB to a predetermined voltage (e.g., about the supply voltage) for write operations. Although not shown here for visual clarity, in some implementations, multiple memory cells 118 may be arranged in multiple rows and coupled to each of the pair of bit lines BL and BLB. The memory array can include multiple columns, which each column including a corresponding set of bit lines having multiple memory cells 118 coupled thereto.

Individual memory cells 118 of the memory array can be addressed by accessing corresponding bit lines BL and BLB (to select by column) and/or corresponding word lines WL or source lines (to select by row). Addressed memory cells can be selected for write and/or read operations. Signals that select memory cells and coordinate read/write operations can be provided by a memory control circuit. The memory control circuit may include any type of control circuit that provides signals to coordinate read or write operations via the circuitry of the memory circuit 100. In some implementations, one or more components of the memory circuit 100 may form at least a part of a memory control circuit.

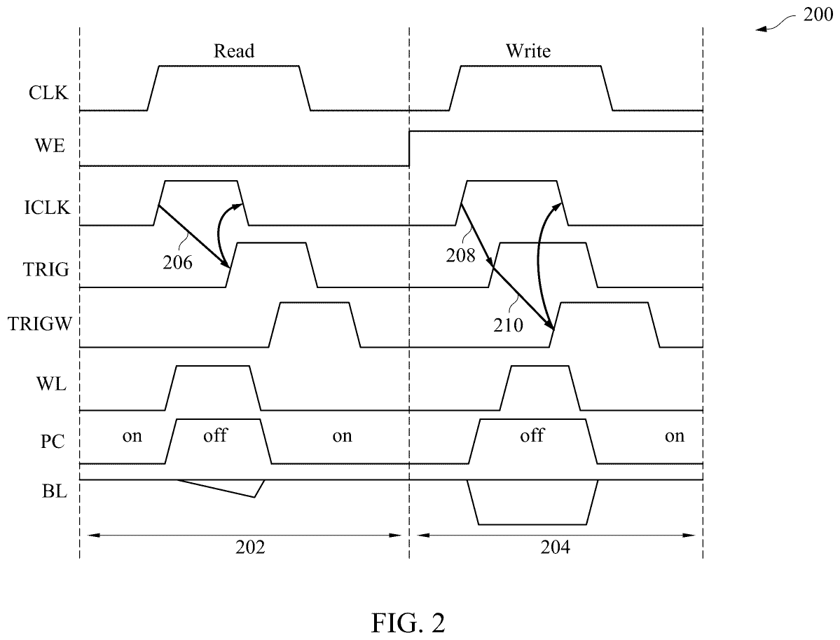

The memory circuit 100 is shown as receiving a clock (CLK) signal and a write enable (WE) signal. The CLK signal is a timing signal that controls the timing of operations in the memory circuit 100. The CLK signal is provided as input to a CLK generation circuit 102. The CLK generation circuit 102 can generate an internal clock (ICLK) signal, which can be a timing signal used to coordinate read/write operations to one or more memory cells 118. The CLK generation circuit 102 can include any type of circuity to generate an ICLK signal as a function of the input clock signal CLK. An example waveform of the ICLK signal relative to the input clock signal CLK is shown in FIG. 2. The WE signal can be a signal that, when in the logic high state (e.g., about the supply voltage of the memory circuit 100) indicates that a write operation is to occur, and when in the logic low state (e.g., about ground voltage) indicates that a read operation is to occur.

The WE signal is provided as input to the OR gate 110 preceded by an inverter, such that an inverted WE signal is provided to the OR gate 110, to the first delay circuit 104, to the AND gate 112, and as a selection input to the multiplexor 108. The AND gate 112 can activate the write driver circuit 122 (e.g., to drive the bit lines to corresponding voltage levels) to perform a write operation when the WE signal and the ICLK signal are both in the logic high state (e.g., about the supply voltage of the memory circuit 100). The write driver circuit 122 can include any circuitry, logic gates, or components structured to write data to one or more memory cells 118 by driving the bit lines BL and BLB to the voltage levels (e.g., logic states) to write data (e.g., received via a memory control circuit, etc.) to the memory cell 118.

The OR gate 110 can control input to the WL driver circuit 116 via the AND gate 114. As shown, when the output of the OR gate 110 and the ICLK signal in the logic high state, the AND gate 114 provides a logic high output that causes the WL driver circuit 116 to be activated, which generates an activation signal on the WL coupled to the memory cell 118. The OR gate 110 is in the logic high state when one of the first delay signal (TRIG) (e.g., generated by the first delay circuit 104) or the inverted write enable signal are in the logic high state. The OR gate 110, in combination with the AND gate 114 enables the WL to be activated according to the ICLK signal during read operations and according to the first delay signal TRIG during write operations, as described further detail in connection with FIG. 2.

The multiplexor 108 provides a reset signal (RST) to the CLK generation circuit 102, which causes the CLK generation circuit 102 to generate a falling edge on the ICLK signal. A rising edge can be generated on the ICLK signal when the CLK generation circuit 102 receives the next rising edge via the input CLK signal. As shown, the multiplexor 108 is controlled by the write enable signal, such that the first delay signal TRIG generates the RST signal during read operations (e.g., WE in the logic low state) and a second delay signal (TRIGW) generates the RST signal during write operations.

Each of the first delay circuit 104 and the second delay circuit 106 can include any suitable delay circuitry to generate a delayed ICLK signal. The amount of delay generated by the first delay circuit 104 may be different depending on the logic state of the WE signal. For example, the first delay circuit 104 may generate a first delay signal TRIG in the same state as the ICLK signal subject to a first amount of delay during a read operation (e.g., WE signal in a logic low state). Furthering this example, the first delay circuit 104 can generate a first delay signal TRIG in the same state as the ICLK signal subject to a second amount of delay during a write operation (e.g., WE signal in a logic high state). The second delay circuit 106 can include any suitable type of delay circuitry to generate a second delay signal TRIGW having the same logic state of the first delay signal TRIG subject to a further amount of delay. As shown, the first delay circuit 104 and the second delay circuit 106 are in series. Examples of delays generated using the first delay circuit 104 and the second delay circuit 106 during read and write operations are shown in FIG. 2.

Referring to FIG. 2 in the context of the components described in connection with FIG. 1, illustrated is a diagram 200 showing example waveforms of signals that can propagate through the memory circuit shown in FIG. 1 during memory operations, in accordance with some embodiments. The diagram 200 shows a read operation 202 followed by a write operation 204. During the read operation 202, the write enable signal WE is in the logic low state, and the memory operation is initiated at the rising edge of the input clock signal CLK. A corresponding rising edge is generated on the ICLK signal (e.g., by the clock generation circuit 102). Each of the pre-charge (PC) signals (e.g., as a direct path from the ICLK signal) and the word line signal WL (e.g., as an output from the WL driver circuit 116) are set to logic high via the ICLK signal. In this example, the PC signal is active low, such that pre-charging is performed while the PC signal is in the logic low state.

As shown, a logic high signal is generated via on the first delay signal TRIG following a first amount of delay 206 (e.g., created via the first delay circuit 104). As the first delay signal TRIG transitions to logic high, the reset signal RST of the CLK generation circuit 102 is activated (e.g., via the multiplexor 108) and the ICLK signal transitions to logic low. The ICLK signal transitioning to logic low state causes the WL signal and the PC signal to each transition to the logic low state.

The first amount of delay 106 generated by the first delay circuit 104 for the TRIG signal for the read operation 202 can correspond to an amount of time for the BL signal to relax according to the read operation, which may be a function of the circuitry or components making up the memory cell. As described herein, the first delay circuit 104 can generate different amounts of delay on the first delay signal TRIG for read and write operations. Although the second delay signal TRIGW is generated by the second delay circuit 106 according to a second amount of delay, the second delay signal TRIGW is not necessarily used for controlling any components or signals for performing the read operation 202.

In this example, a write operation 204 follows the read operation 202. During the write operation 204, the write enable signal WE is in the logic high state, and the memory operation is initiated at the next rising edge of the input clock signal CLK. A corresponding rising edge is generated on the ICLK signal (e.g., by the clock generation circuit 102). As in the read operation, the PC signal (e.g., as a direct path from the ICLK signal) is set to logic high via the ICLK signal. Additionally, the bit line signals BL and BLB are controlled by the write driver circuit 122 to perform the write operation. As shown, one of the bit line signals BL or BLB is pulled to logic low on the rising edge of the ICLK signal.

As shown, a logic high signal is generated via on the first delay signal TRIG following a first amount of write delay 208 (e.g., created via the first delay circuit 104). The first amount of write delay 208 generated by the first delay circuit 104 during the write operation 204 can be different from the first amount of delay 206 generated during the read operation 202. Unlike during the read operation, as the first delay signal TRIG transitions to logic high, the reset signal RST of the CLK generation circuit 102 is not activated due to the multiplexor 108 selecting the second delay signal TRIGW according to the WE signal in the logic high state.

As the first delay signal TRIG transitions to logic high, the WL signal is also driven to logic high by the write driver 122. The first amount of write delay 208 can be configured such that at least one bit line BL has fully transitioned to the logic low state, prior to asserting the WL signal in the logic high state, thereby avoiding contention at the storage node of the corresponding memory cell. Following a second amount of delay 210, the second delay signal TRIGW transitions to logic high. The rising edge of the second delay signal TRIGW causes the reset signal of the CLK generation circuit 102 to activate, causing the ICLK signal to transition to a logic low state.

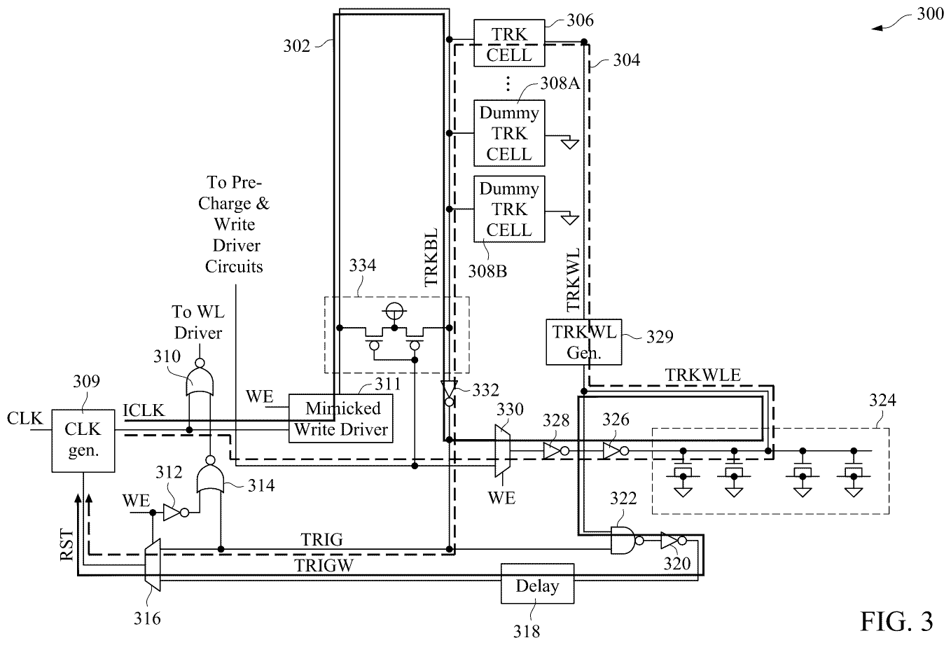

As the ICLK signal transitions to the logic low state, each of the WL signal and the PC signal also transition to the logic low state. Additionally, the bit line signal BL that was pulled to the logic low state by the write driver circuit 122 transitions back to a logic high state, as shown. Each of the first amount of delay 206, the first amount of write delay 208, and the second amount of delay 210 can be determined by modeling signal propagation through “dummy” or “tracking” memory cells and components, as described in connection with FIGS. 3, 4, and 7.

Referring to FIG. 3 in the context of the components described in connection with FIG. 1, illustrated is a diagram of an example memory circuit 300 showing read and write paths for different, in accordance with some embodiments. The memory circuit 300 may be similar to the memory circuit 100 shown in FIG. 1, with the first and second delay circuits 104 and 106 generated using components and signals that model signal paths through the memory cells and components of the memory circuit 100.

Various embodiments of the circuits and logic gates that implement the memory circuit 300 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like. It should be understood that the memory circuit 300 shown in FIG. 3 can be a portion of a larger memory circuit that includes memory cells (e.g., memory cells 118) and corresponding read/write circuitry. For example, although not shown here for visual clarity, various additional circuitry may be included to address (e.g., select) or otherwise access memory cells or to perform different memory operations, including but not limited to CIM operations, write operations, or read operations, among others.

The memory circuit 300 is shown as including a CLK generation circuit 309, first and second NOR gates 310 and 314, and an inverter 312. The CLK generation circuit 309 may be similar to the CLK generation circuit 102 of the memory circuit 100 of FIG. 1, and the first and second NOR gates 310 and 314 can implement similar logical functionality as the OR gate 110 and the AND gate 114 of the memory circuit 100 of FIG. 1. The memory circuit 300 is shown as including the multiplexor 316, which may be similar to the multiplexor 108 of the memory circuit 100 of FIG. 1. As shown, the multiplexor 316 selects between the first delay signal TRIG and the second delay signal TRIGW according to the write enable signal WE.

As shown, the CLK generation circuit 309 receives the input clock signal CLK and generates an internal clock signal ICLK. The memory circuit 300 also receives the write enable signal WE as input. Generating the first delay signal TRIG and the second delay signal TRIGW can be a function of the memory operation being performed. As described in connection with FIG. 2, the amount of delay generated during a read operation can be different from the delay generated during a write operation. These differences are generated according to two different pathways through the memory circuit 300, the write pathway 302 for write operations and the read pathway 304 for read operations.

To generate delay for write operations via the write pathway 302, the pre-charge circuit 334 first operates by pre-charging the tracking bit line (TRKBL) signal to a logic high state, prior to assertion of the write enable signal WE (e.g., prior to any memory operations occurring). The pre-charge circuit, in this example, includes two PMOS transistors, each with a first source/drain terminal tied to the supply voltage, and a second source/drain terminal tied to the TRKBL node. The gate of the PMOS transistors is coupled to the ICLK signal, such that TRKBL node is set to about the supply voltage (e.g., logic high) when the ICLK signal is logic low (e.g., between memory operations). In some implementations, the size of the path defining the TRKBL node can correspond to a length of the signal path for the write driver 122 to the bit lines BL and BLB of FIG. 1.

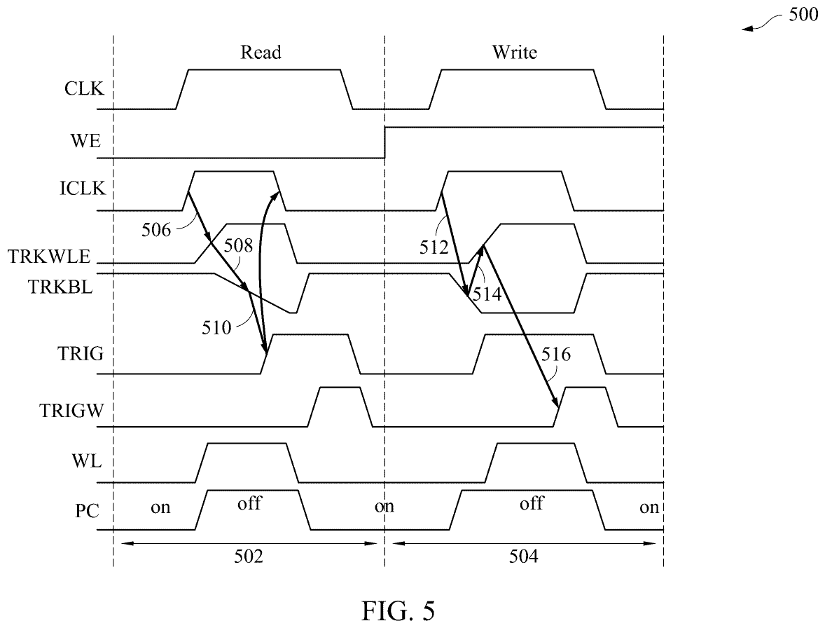

During a write operation, the ICLK signal and the write enable WE are in a logic high state, activating the mimicked write driver circuit 311 and deactivating the pre-charge circuit 334. The mimicked write drive circuit 311, when activated, mimics the delay and behavior of the write drive circuit 122, causing the TRKBL node to begin falling to logic low. Further details of this waveform are shown in FIG. 5. As the write enable signal is in the logic high state, a second multiplexor 330 selects the output of the inverter 332 to provide an output to the second inverter 328. The output of the inverter 332 is provided as the first delay signal TRIG for the write operation.

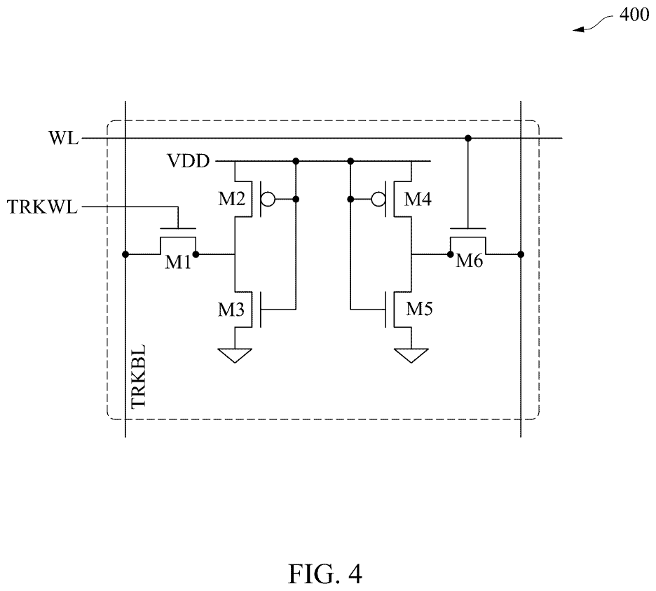

Using inverted voltage at the TRKBL node generated according to the mimicked write driver circuit 311 enables the first delay signal TRIG to only be generated once the bit line of the memory cell has been fully pulled down to about ground voltage. This amount of time is modeled by having a corresponding set of tracking (TRK) memory cell 306 and the dummy tracking (TRK) memory cells 308A and 308B, which correspond to a number of memory cells coupled to the actual bit line of the memory circuit (e.g., the number of memory cells 118 coupled to the bit line BL of the memory circuit 100). The dummy TRK memory cells 308A and 308B are coupled to ground, mimicking the electrical characteristics of unselected memory cells coupled to the bit line. Preserving this relationship enables generation of a precise amount of delay that corresponds to the physical characteristics of the memory cells being written to during the write operation. Examples of tracking memory cells are shown in FIG. 4.

Referring to FIG. 4, illustrated is a diagram of an example tracking memory circuit 400 (sometimes referred to as a tracking memory cell 400) of the memory circuits described herein, in accordance with some embodiments. The tracking memory circuit 400 includes six transistors M1, M2, M3, M4, M5, and M6, each of which implement a portion of the circuitry to model signal transitions, capacitance, and resistance of SRAM memory cells (e.g., the memory cell 118). Although each of the transistors M1-M6 of the tracking memory circuit 400 are shown as one transistor, embodiments are not limited thereto. For example, each of the transistors may include multiple transistors (“sub-transistor(s)”) that are connected to one another in parallel. For example, in an embodiment, each of the sub-transistors of any transistor described herein can include respective gate, drain, and source terminals, each of which may be connected to one another in parallel.

The tracking memory circuit 400 includes transistors M1, M2, M3, M4, M5, and M6. In some implementations, the transistors M2 and M4 are pMOSFET transistors, and the transistors M1, M3, M5, and M6 are nMOSFET transistors. It is appreciated that each of the transistors M1-M6 can include any of various other types of transistors (e.g., bipolar junction transistors, high-electron-mobility transistors, etc.) while remaining within the scope of the present disclosure. As shown, the sources of the transistors M2 and M4, and M5 are electrically coupled with a supply voltage VDD, and the sources of the transistors M3 and M5 are connected to a ground voltage. The drain terminals of the transistors M2 and M4 are respectively coupled to the drain terminals of the transistors M3 and M5. As shown, the gate terminals of the transistors M2, M3, M4, and M5 are each coupled to the supply voltage VDD.

A first source/drain terminal of the transistor M1 is coupled to the TRKBL node (e.g., the TRKBL node of the memory circuit 300 of FIG. 3) and a second source/drain terminal of the transistor M1 is coupled to the drain terminals of the transistors M2 and M3. The gate terminal of the transistor M1 is coupled to the tracking word line (TRKWL) signal (e.g., the TRKWL signal of the memory circuit 300 of FIG. 3). A first source/drain terminal of the transistor M6 is coupled to a second node (e.g., a ground node, an inverse of the TRKBL node, etc.) and a second source/drain terminal of the transistor M6 is coupled to the drain terminals of the transistors M4 and M5. The gate terminal of the transistor M6 is coupled to a word line signal WL (e.g., the WL signal of the memory circuit 100 of FIG. 1).

Referring back to FIG. 3, to generate the second delay signal TRIGW, the second inverter 332 receives the voltage at the TRKBL node (which is falling according to the delay of the mimicked write drive circuit 311). As noted above, the first amount of delay along the write pathway 302 is generated according to the output of the mimicked write driver circuit 311 affecting the pre-charged voltage level of the TRKBL. The second delay signal TRIGW is generated according to the first delay signal TRIG, as selected via the multiplexor 330 according to the write enable signal WE being in the logic high state. Via the selection, the multiplexor 330 provides the TRIG signal as input to the inverters 328 and 326, acting as a buffer for the TRIG signal.

The output of the inverter 326 is coupled to a sequence of parallel transistors 324 that are configured as capacitors. As shown, each source/drain terminal of the sequence of parallel transistors 324 is coupled to a ground voltage and the gate terminals of each of the sequence of parallel transistors 324 is coupled to the output of the inverter 326. The physical parameters of the sequence of parallel transistors 324 can be selected such that the equivalent resistance and capacitance created via the sequence of parallel transistors 324 is about equal to the resistance and capacitance of the actual word line WL node of the memory array (e.g., the WL line coupled to the memory cells 118 of the memory circuit 100 of FIG. 1).

Mimicking the characteristics of the word line creates further delay that ensures the word line of the memory cell being written fully transitions fully to the logic high state following the first delay signal TRIG. The mimicked word line signal is generated at the tracking word line enable (TRKWLE) signal, as shown. As the memory operation along the write pathway 302 is a write operation, the tracking word line (TRKWL) generation circuit 329 is deactivated and does not conduct. The mimicked WL signal on the TRKWLE node is provided as input to the NAND gate 322, along with the first delay signal TRIG. The NAND gate 322 outputs a signal in the logic low state (e.g., about the ground voltage) when both the first delay signal TRIG and the signal on the TRKWLE node is in the logic high state, and outputs a signal in the logic high state otherwise.

The output of the NAND gate is provided to as input to the inverter 320. The inverter 320 provides an output signal in the logic high state (e.g., about the supply voltage) when the first delay signal TRIG and the signal on the TRKWLE node are in the logic high state, and outputs a signal in the logic low state (e.g., about the ground voltage) otherwise. During a write operation, the output of the inverter 320 is in the logic low state until the first delay signal TRIG is generated and the capacitors of the TRKWLE node are fully charged by the output of the inverter 326, at which the inverter 320 transitions to a logic high state. The output of the inverter 320 is provided as input to a delay circuit 318. The delay circuit 318 can include any number of inverters in an inverter chain to establish a proper amount of delay for writing data to the memory cell (e.g., an amount of time for asserting the word line WL to write to the memory array).

The output of the delay circuit 318 is provided as the second delay signal TRIGW. During a write operation, the write enable signal WE is in the logic high state, which causes the multiplexor 316 to select the second delay signal TRIGW as the reset signal RST. As the second delay signal TRIGW transitions to a logic high state, the reset of the CLK generation circuit 309 is activated, causing the ICLK signal to transition to a logic low state until the next rising edge of the input clock signal CLK.

When the ICLK signal transitions to a logic low state, the mimicked write driver circuit 311 is deactivated, causing the TRKBL node to be charged by the pre-charge circuit 334 to about the supply voltage. This causes the output of the NOR gate 310 to transition to the logic low state, deactivating the write signal. The transition of ICLK to the logic low state also disables the write driver circuit (e.g., the write driver circuit 122 of FIG. 1) and activates the pre-charge circuit (e.g., the PC circuit 120), causing the bit lines BL and BLB to transition to the logic high state. The output of the inverter 332 transitions to the logic low state (e.g., as a logical inverse of the supply voltage on the TRKBL node), causing the first delay signal TRIG to transition to the logic low state. The transition of the first delay signal TRIG to the logic low state causes the second delay signal TRIGW to transition to the logic low state, subject to the delay of the delay circuit 318, which completes the write operation.

During a read operation, the read pathway 304 is activated to generate the first delay signal TRIG and the second delay signal TRIGW. During a read operation, the ICLK signal is in a logic high state and the write enable WE is in a logic low state, deactivating the mimicked write drive circuit 311 and the pre-charge circuit 334. As the write enable signal is in the logic low state, the second multiplexor 330 selects the ICLK signal to provide an output to the inverter 328. The inverters 328 and 326 operate as a buffer for the ICLK signal during the read operation. The output of the inverter 326 is provided to the sequence of parallel transistors 324, which mimics the physical parameters of the actual word line WL node of the memory array (e.g., the WL line coupled to the memory cells 118 of the memory circuit 100 of FIG. 1), as described herein.

When the sequence of parallel transistors 324 are sufficiently charged, a logic high signal is generated at the TRKWLE node. As the write enable signal WE is in the logic low state indicating a read operation, the TRKWL generation circuit 329 to activate. The TRKWL generation circuit 329 generates a signal that asserts the gate terminal of an access transistor (e.g., the transistor M1 of FIG. 4) of the TRK memory cell 306. As the pre-charge circuit 334 is deactivated, asserting the gate terminal of the access transistor of the TRK memory cell 306 causes the signal at the TRKBL node to transition to the logic low state. As noted above, the mimicked write driver circuit 311 is deactivated due to the write enable signal WE being in the logic low state and does not conduct.

When the TRKBL node transitions to the logic low state (e.g., as the charge at the TRKBL is discharged to ground via the transistors of the TRK memory cell 306), the output of the inverter 332 transitions to a logic high state, causing the first delay signal TRIG to transition to a logic high state (e.g., about the supply voltage). The amount of time taken for the TRKBL node to transition to the logic low state corresponds to the first amount of delay (e.g., the first amount of delay 206 of FIG. 2) during read operations.

During the read operation, the write enable signal is in the logic low state, causing the multiplexor 316 to select the first delay signal TRIG as the reset signal RST. The reset signal RST, when activated, causes the ICLK signal to transition to the logic low state. This causes the output of the NOR gate 310 and the TRKWLE node to transition to the logic low state, disabling (e.g., pulling to logic zero) the word line signal WL and the TRKWL signals, respectively. The pre-charge circuit 334 is also reactivated when the ICLK signal is in the logic low state, causing the TRKBL node to transition to the logic high state, thereby completing the read operation. Example waveforms corresponding to read and write operations are shown in FIG. 5.

Referring to FIG. 5 in the context of the components described in connection with FIG. 3, illustrated is a diagram 500 of example waveforms of signals that can propagate through the memory circuit shown in FIG. 3 during memory operations, in accordance with some embodiments. The diagram 500 shows a read operation 502 followed by a write operation 504. During the read operation 502, the write enable signal WE is in the logic low state, and the memory operation is initiated at the rising edge of the input clock signal CLK. A corresponding rising edge is generated on the ICLK signal (e.g., by the CLK generation circuit 309). Each of the PC signals (e.g., as a direct path from the ICLK signal) and the word line signal WL are set to logic high via the ICLK signal, as described herein. In this example, the PC signal is active low, such that pre-charging (e.g., via the pre-charge circuit 120 and the pre-charge circuit 334) is performed while the PC signal is in the logic low state.

As shown, the transition of the ICLK signal to a logic high state causes the TRKWLE to transition to a logic high state over a first time period 506 (e.g., as the capacitors of the sequence of parallel transistors 324 are charged). Once the TRKWLE is charged to generate the TRKWL signal, the TRKBL node begins to discharge over a second time period 508 (e.g., via the transistors of the TRK memory cell 306). Once the TRKBL node transitions to a sufficiently low voltage level, the output of an inverter (e.g., the inverter 332) generates the first delay signal TRIG in the logic high state at a third time period 510, as shown. As described herein, the transition of the first delay signal TRIG to logic high causes the ICLK signal to be reset to a logic low state. The transition of the ICLK signal causes the word line signal WL and the pre-charge signal PC to transition to the logic low state. The TRKBL node is then pre-charged back to the logic high state, causing the inverter to change the logic state of the first delay signal TRIG to the logic low state, completing the read operation.

In this example, a write operation 504 follows the read operation 502. During the write operation 504, the write enable signal WE is in the logic high state, and the memory operation is initiated at the next rising edge of the input clock signal CLK. A corresponding rising edge is generated on the ICLK signal (e.g., by the clock generation circuit 102). As in the read operation, the PC signal (e.g., as a direct path from the ICLK signal) is set to logic high via the ICLK signal, disabling the pre-charge operation of the bit lines BL and the TRKBL node. Additionally, the ICLK signal causes a mimicked write driver circuit (e.g., the mimicked write driver circuit 311) to transition the TRKBL node to logic zero over at a fourth time period 512.

When voltage at the TRKBL node falls to a threshold voltage while being pulled to the logic low state (e.g., subject to the capacitance and resistance of the TRK memory cell 306 and the dummy TRK memory cells 308A and 308B), the output of an inverter (e.g., the inverter 332) transitions to the logic high state, generating the logic high TRIG signal at the second time period 514. The logic high TRIG signal causes the word line WL to transition to the logic high state and begins charging the capacitors of the TRKWLE node towards the logic high state, as shown. When the voltage of the TRKWLE node reaches a threshold voltage, an inverter chain begins generating the second delay signal TRIGW in the logic high state according to a delay period 516.

Transitioning the second delay signal TRIGW to the logic high state causes the ICLK signal to be reset to a logic low state. The transition of the ICLK signal causes the word line signal WL and the pre-charge signal PC to transition to the logic low state. The TRKBL node is then pre-charged back to the logic high state, causing the inverter to change the logic state of the first delay signal TRIG to the logic low state. This causes the second delay signal TRIGW to transition to the logic low state, subject to the delay of the inverter chain (e.g., the delay circuit 318), completing the write operation 504.

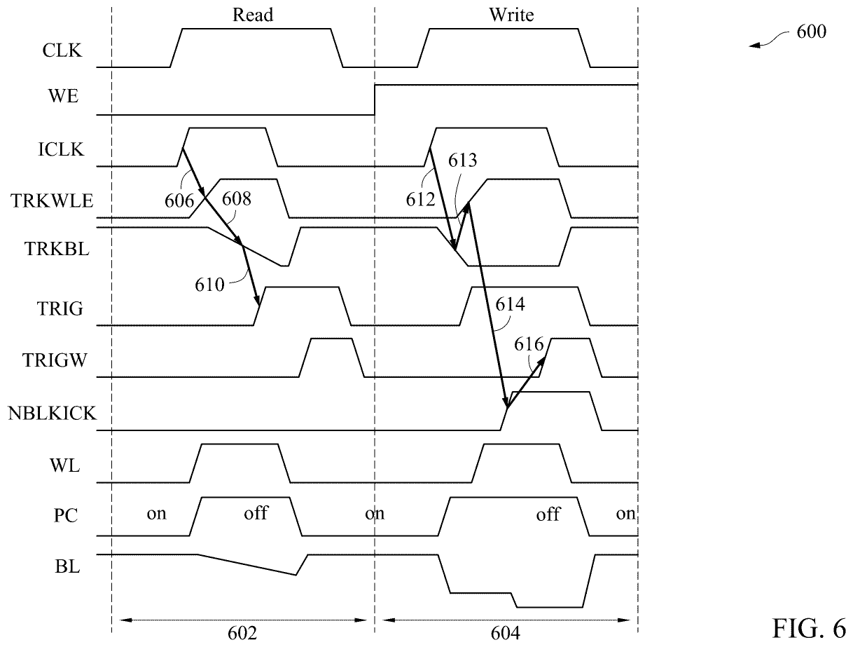

Referring to FIG. 6 in the context of the components described in connection with FIG. 3, illustrates a diagram 600 of example waveforms of signals that can propagate through the memory circuit shown in FIG. 3 involving signals (e.g., NBLKICK) for a write assistance circuit, in accordance with some embodiments. The diagram 500 shows a read operation 502 followed by a write operation 504, where the write operation involves an additional write assistance signal NBLKICK to a write assistance circuit that facilitates write operations to certain memory cells. In this example, the NBL kick signal may be provided via the output node of the inverter 320 of the memory circuit 300 of FIG. 3.

During the read operation 602, the write enable signal WE is in the logic low state, and the memory operation is initiated at the rising edge of the input clock signal CLK. A corresponding rising edge is generated on the ICLK signal (e.g., by the CLK generation circuit 309). Each of the PC signals (e.g., as a direct path from the ICLK signal) and the word line signal WL are set to logic high via the ICLK signal, as described herein. In this example, the PC signal is active low, such that pre-charging (e.g., via the pre-charge circuit 120 and the pre-charge circuit 334) is performed while the PC signal is in the logic low state. This causes the voltage potential at the bit line node coupled to the memory cell being read (e.g., the memory cell 118) to begin falling, according to the charge stored at the memory cell.

As shown, the transition of the ICLK signal to a logic high state causes the TRKWLE to transition to a logic high state over a first time period 606 (e.g., as the capacitors of the sequence of parallel transistors 324 are charged). Once the TRKWLE is charged to generate the TRKWL signal, the TRKBL node begins to discharge over a second time period 608 (e.g., via the transistors of the TRK memory cell 306). Once the TRKBL node transitions to a sufficiently low voltage level, the output of an inverter (e.g., the inverter 332) generates the first delay signal TRIG in the logic high state at a third time period 610, as shown. The NBLKICK output can remain logic low during the read operation (e.g., via one or more logic gates, etc.). As described herein, the transition of the first delay signal TRIG to logic high causes the ICLK signal to be reset to a logic low state. The transition of the ICLK signal causes the word line signal WL and the pre-charge signal PC to transition to the logic low state. The TRKBL node is then pre-charged back to the logic high state, causing the inverter to change the logic state of the first delay signal TRIG to the logic low state, completing the read operation.

In this example, a write operation 604 follows the read operation 602. The write operation 604 involves activating the write assistance signal NBLKCIK. During the write operation 604, the write enable signal WE is in the logic high state, and the memory operation is initiated at the next rising edge of the input clock signal CLK. A corresponding rising edge is generated on the ICLK signal (e.g., by the clock generation circuit 102). As in the read operation, the PC signal (e.g., as a direct path from the ICLK signal) is set to logic high via the ICLK signal, disabling the pre-charge operation of the bit lines BL and the TRKBL node. Additionally, the ICLK signal causes a mimicked write driver circuit (e.g., the mimicked write driver circuit 311) to transition the TRKBL node to logic zero over at a fourth time period 612.

When voltage at the TRKBL node falls to a threshold voltage while being pulled to the logic low state (e.g., subject to the capacitance and resistance of the TRK memory cell 306 and the dummy TRK memory cells 308A and 308B), the output of an inverter (e.g., the inverter 332) transitions to the logic high state, generating the logic high TRIG signal at the second time period 613. The logic high TRIG signal causes the word line WL to transition to the logic high state and begins charging the capacitors of the TRKWLE node towards the logic high state, as shown. When the voltage of the TRKWLE node reaches a threshold voltage, the write assistance signal NBLKICK transitions to logic high at the third time period 614 according to the output of a second inverter (e.g., the inverter 320). Additionally, an inverter chain (e.g., the delay circuit 318) begins generating the second delay signal TRIGW in the logic high state according to a delay period 616.

As shown, the bit line signal BL of the memory cell being written to begins transitioning to logic low when the ICLK signal is activated. Additionally, the delay circuits described herein activate the write assistance signal NBLKICK shortly after asserting the word line signal WL, causing the bit line to be pulled below ground voltage after the word line WL is fully asserted to facilitate the write operation. The use of delays to facilitate the generation of the NBLKICK signal reduces dynamic power consumption of write operations using write assistance circuits compared to conventional memory circuits.

Transitioning the second delay signal TRIGW to the logic high state causes the ICLK signal to be reset to a logic low state. The transition of the ICLK signal causes the word line signal WL and the pre-charge signal PC to transition to the logic low state. The TRKBL node is then pre-charged back to the logic high state, causing the inverter to change the logic state of the first delay signal TRIG to the logic low state. This causes the second delay signal TRIGW and the write assistance signal NBLKICK to transition to the logic low state, completing the write operation 604.

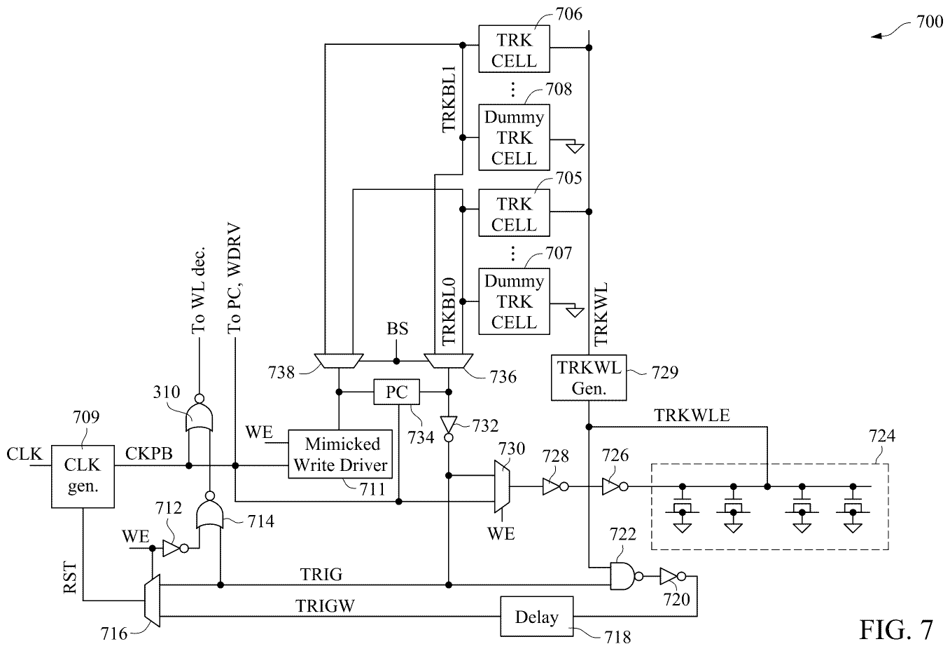

Referring to FIG. 7, illustrated is a diagram of an example memory circuit 700 similar to the memory circuit 300 shown in FIG. 3, implemented for multiple memory banks, in accordance with some embodiments. The memory circuit 700 may also be similar to the memory circuit 100 shown in FIG. 1, with the first and second delay circuits 104 and 106 generated using components and signals that model signal paths through the memory cells and components of the memory circuit 100. The memory circuit 700 provides implementations of the first and second delay circuits 104 and 106 in the context of a multibank memory system.

Various embodiments of the circuits and logic gates that implement the memory circuit 700 may include various transistors. The transistors described herein may have a certain type (n-type or p-type), but embodiments are not limited thereto. The transistors can be any suitable type of transistor including, but not limited to, MOSFET, CMOS transistors, PMOS, NMOS, BJT, high voltage transistors, high frequency transistors, PFETs/NFETs, FinFETs, planar MOS transistors with raised source/drains, nanosheet FETs, nanowire FETs, or the like. It should be understood that the memory circuit 700 shown in FIG. 7 can be a portion of a larger memory circuit that includes memory cells (e.g., memory cells 118) and corresponding read/write circuitry. For example, although not shown here for visual clarity, various additional circuitry may be included to address (e.g., select) or otherwise access memory cells or to perform different memory operations, including but not limited to CIM operations, write operations, or read operations, among others.

The memory circuit 700 is shown as including a CLK generation circuit 709, first and second NOR gates 710 and 714, NAND gate 722, and inverters 712, 732, 728, 726, and 720. Each of the CLK generation circuit 709, the first and second NOR gates 710 and 714, the NAND gate 722, and the inverters 712, 732, 728, 726, and 720 can be similar to each of the structure and functionality of the CLK generation circuit 309, the first and second NOR gates 310 and 314, the NAND gate 322, and the inverters 314, 332, 328, 326, and 320 described in connection with the memory circuit 300 of FIG. 3.

The memory circuit 700 is shown as including the pre-charge circuit 734, the multiplexors 716 and 730, the sequence of parallel transistors 724, the delay circuit 718, and the mimicked write driver circuit 711, each of which may be similar to the pre-charge circuit 334, the multiplexors 316 and 330, the sequence of parallel transistors 324, the delay circuit 318, and the mimicked write driver circuit 311 described in connection with the memory circuit 300 of FIG. 3. The memory circuit 700 is shown as including multiple memory banks, with the first memory bank including the TRK memory cell 705 and one or more dummy TRK memory cells 707, and the second memory bank including the TRK memory cell 706 and one or more dummy TRK memory cells 708, which may be similar to the TRK memory cell 306 and the one or more dummy TRK memory cells 308A and 308B described in connection with the memory circuit 300 of FIG. 3.

The memory circuit 700 can implement similar read/write pathways as the write/read pathways 302 and 304, respectively, of the memory circuit 300 of FIG. 3. Additionally, the memory circuit 700 can receive the bank selection (BS) signal from one or more memory controller circuits, which selects between the memory banks of the memory device during read/write operations. Although two memory banks are shown here (corresponding to the TRKBL0 and TRKBL1 nodes), it should be understood that the number of memory banks of TRK cells and dummy TRK cells can match the number of memory banks of the memory device in which the memory circuit 700 is implemented. Although only one TRKWL signal is shown, it should be understood that the memory circuit 700 can include, in some implementations, additional multiplexors, sequences of parallel transistors 734, and TRKWL generation circuits 729 to facilitate generation of respective TRKWL signals for each bank of memory cells.

The memory circuit 700 includes the multiplexors 736 and 738, each of which are controlled by the bank select signal BS. When the bank select signal BS is in the logic low state, the multiplexors 736 and 738 couple the TRKBL0 (corresponding to selection of memory Bank 0) to the inverter 732 and the mimicked write driver circuit 711, respectively. When the bank select signal BS is in the logic high state, the multiplexors 736 and 738 couple the TRKBL1 (corresponding to selection of memory Bank 1) to the inverter 732 and the mimicked write driver circuit 711, respectively. Each of the pathways along the TRKBL0 and TRKBL1 nodes can mimic the pathways of the bit lines of the memory banks in the memory device to which the TRKBL0 and TRKBL1 nodes correspond.

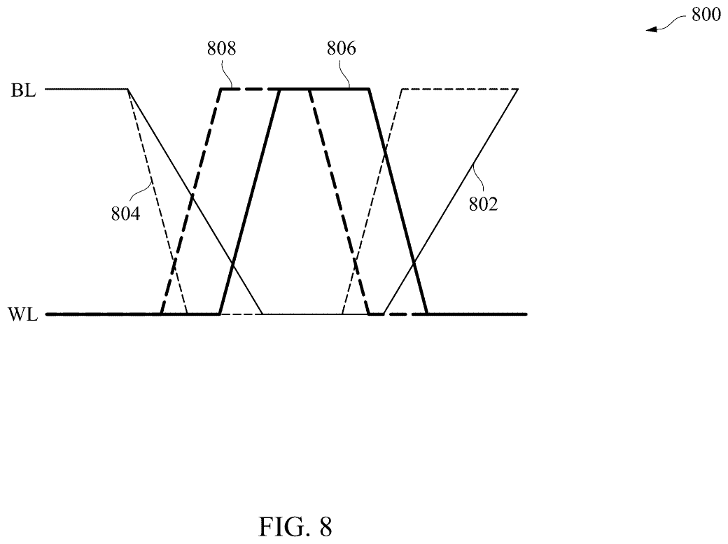

When performing a read/write operation to Bank 0, the input bank selection signal is in the logic low state, such that the first delay signal TRIG and the second delay signal TRIGW are generated according to the delays associated with the memory devices of Bank 0. When performing a read/write operation to Bank 1, the input bank selection signal is in the logic high state, such that the first delay signal TRIG and the second delay signal TRIGW are generated according to the delays associated with the memory devices of Bank 1. Examples of waveform indicating differences in delays between different memory banks are shown in FIG. 8.

Referring to FIG. 8, illustrated is a diagram 800 of example waveforms of signals that can propagate through the memory circuit shown in FIG. 7, in accordance with some embodiments. In the diagram 800, multiple waveforms for different memory banks (e.g., selected according to the bank select signal BS) are shown. In this example, the electrical characteristics of a first bit line of a first memory bank cause the first bit line signal 803 (e.g., to pull the bit line to ground voltage during write operations) on the bit line BL to have a first slope that is greater than a second slope of the second bit line signal 804 of a second bit line of a second memory bank.

However, the delay signals (e.g., TRIG, TRIGW) described herein cause the word line signal WL to be generated as a function of the bit line signal BL being pulled to ground. As a result, a first word line signal 806 on a first word line of the first memory bank is set to logic high after the first bit line signal 802 has been sufficiently lowered. Likewise, for the second memory bank, a second word line signal 808 on a second word line of the second memory bank is set to logic high after the second bit line signal 804 has been sufficiently lowered, regardless of the slope of each signal. This enables generation of a word line signal having optimal assertion timing, reducing overall power consumption for write operations in multibank memory devices.

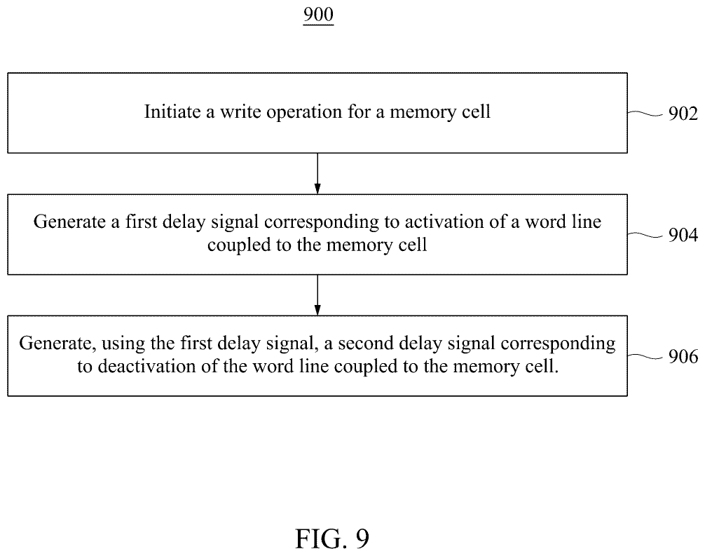

FIG. 9 illustrates a flowchart of an example method 900 of operating an example memory circuits that implements delays to reduce contention during memory operations, in accordance with some embodiments. The method 900 may be used to operate a memory circuit (e.g., the memory circuit 100, 300, 700, etc.). For example, at least some of the operations described in the method 900 use layouts and schematics described in FIGS. 1, 3, and 7. It is noted that the method 900 is merely an example and is not intended to limit the present disclosure. Accordingly, it is understood that additional operations may be provided before, during, and after the method 900 of FIG. 9, and that some other operations may only be briefly described herein.

In brief overview, the method 900 starts with operation 902 of initiating a write operation for a memory cell. The method 900 proceeds to operation 904 of generating a first delay signal corresponding to activation of a word line coupled to the memory cell. The method 900 proceeds to operation 906 of generating, using the first delay signal, a second delay signal corresponding to deactivation of the word line coupled to the memory cell.

Referring to operation 902, a write operation for a memory cell (e.g., the memory cell 118) is initiated. For example, a memory controller can provide an input clock signal (e.g., the input clock signal CLK) and a write enable signal (e.g., the write enable signal WE) to a memory circuit (e.g., the memory circuit 100, 300, 700, etc.). In some implementations, a bank select signal BS can be provided to the memory circuit to select the bank of the memory cell. The write enable signal and the clock signal can be provided as input to one or more circuit components (e.g., of the memory circuit 300 or 700, the delay circuits 104, 106, etc.) to generate delay signals (e.g., TRIG, TRIGW, etc.) to reduce contention at the memory cell during the write operation.

Referring to operation 904, a first delay signal (e.g., TRIG) corresponding to activation of a word line (e.g., WL) coupled to the memory cell (e.g., the memory cell 118) is generated. Generating the first delay signal TRIG can be initiated by generating an internal clock signal ICLK (e.g., via a CLK generation circuit 309, 709). The ICLK signal and the write enable circuit can be provided to one or more components (e.g., the mimicked write driver circuit 311, 711, the pre-charge circuit 334, 734, the TRK memory cell 306, the dummy TRK cells 308A, 308B) to generate the first delay signal TRIG, as described in connection with FIGS. 3-5 and 7.

The first delay signal TRIG in a logic high state when a mimicked bit line for the memory cells (e.g., the TRKBL node) is transitioned to a logic low state using a mimicked write driver circuit (e.g., the mimicked write driver circuit 311, 711). The transition of the first delay signal TRIG to a logic high state can activate a word line driver circuit (e.g., the word line driver circuit 116) to generate a logic high output on the word line of the memory circuit. The delay components can be configured such that the word line driver circuit asserts logic high on the word line only after at least one bit line of the selected memory is pulled to a logic zero state (e.g., by a write driver circuit 122), reducing contention at the memory cell.

Referring to operation 906, a second delay signal (e.g., TRIGW) is generated using the first delay signal. The second delay signal TRIGW corresponds to deactivation of the word line coupled to the memory cell. The second delay signal TRIGW can be generated using a mimicked word line (e.g., the sequence of parallel transistors 324, 724), which mimics the electrical characteristics (e.g., the capacitance, resistance) of the word line of the memory circuit. Mimicking the word line of the memory circuit enables the second delay signal TRIGW to accommodate for the amount of time it takes for the word line driver circuit (e.g., the word line driver circuit 116) to assert the word line WL in the logic high state. The second delay signal can be generated according to an additional inverter chain (e.g., the delay circuit 318, the delay circuit 718) that is selected to enable the second delay signal to remain asserted according to a write time for the memory cell. Once the mimicked word line signal (e.g., the signal asserted on the TRKWLE node) is in a logic high state and has propagated through the additional inverter chain, the second delay signal TRIGW is generated in a logic high state. The second delay signal TRIGW can cause the internal clock signal ICLK to be reset, thereby causing the other signals in the memory circuit to transition to their pre-operation states, as described in connection with FIGS. 5 and 6. This completes the write operation.

In one aspect of the present disclosure, a memory device is disclosed. The memory device includes a memory cell coupled to a bit line and a word line. The memory device includes a first delay circuit configured to generate a first delay signal to activate a word line driver according upon the bit line of the memory cell transitioning to a logic low state. The memory device includes a second delay circuit configured to generate a second delay signal to deactivate the word line driver according to at least an amount of time to assert the word line coupled to the memory cell.

In another aspect of the present disclosure, a memory circuit is disclosed. The memory circuit includes a bit line and a word line coupled to a memory cell. The memory circuit includes a tracking bit line coupled to a tracking memory cell. The tracking bit line and the tracking memory cell mimic electrical characteristics of the bit line coupled to the memory cell. The memory circuit includes a mimicked write driver device configured to set a voltage of the tracking bit line to a about a ground voltage over a first time period, wherein setting the voltage of the tracking bit line to about the ground voltage causes a word line driver device coupled to the word line to set the word line to a logic low state following the first time period.

In yet another aspect of the present disclosure, a method is disclosed. The method includes initiating a write operation for a memory cell. The method includes generating a first delay signal corresponding to activation of a word line coupled to the memory cell. The method includes generating, using the first delay signal, a second delay signal corresponding to deactivation of the word line coupled to the memory cell.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a memory cell coupled to a bit line and a word line;
a first delay circuit configured to generate a first delay signal to activate a word line driver according upon the bit line of the memory cell transitioning to a logic low state; and
a second delay circuit configured to generate a second delay signal to deactivate the word line driver according to at least an amount of time to assert the word line coupled to the memory cell.

2. The memory device of claim 1, wherein the first delay circuit comprises a tracking bit line node that mimics electrical characteristics of the bit line.

3. The memory device of claim 2, wherein the first delay circuit comprises a pre-charge circuit coupled to the tracking bit line node, the pre-charge circuit configured to charge the tracking bit line node to a supply voltage.

4. The memory device of claim 2, wherein the first delay circuit comprises at least one tracking memory cell coupled to the tracking bit line node that mimics second electrical characteristics of the memory cell coupled to the bit line.

5. The memory device of claim 2, wherein the first delay circuit comprises a mimicked write driver circuit configured to set a voltage of the tracking bit line node to the logic low state.

6. The memory device of claim 1, wherein the second delay circuit comprises a sequence of parallel transistors having a capacitance and a resistance that mimics electrical characteristics of the word line coupled to the memory cell.

7. The memory device of claim 1, further comprising an internal clock generation circuit configured to generate an internal clock signal for at least the first delay circuit.

8. The memory device of claim 7, wherein the internal clock generation circuit receives one of the first delay signal or the second delay signal as a reset signal.

9. The memory device of claim 1, further comprising a write driver circuit coupled to the bit line.

10. The memory device of claim 1, further comprising a pre-charge circuit coupled to the bit line.

11. A memory circuit, comprising:
a bit line and a word line coupled to a memory cell;
a tracking bit line coupled to a tracking memory cell, wherein the tracking bit line and the tracking memory cell mimic electrical characteristics of the bit line coupled to the memory cell; and
a mimicked write driver device configured to set a voltage of the tracking bit line to a about a ground voltage over a first time period, wherein setting the voltage of the tracking bit line to about the ground voltage causes a word line driver device coupled to the word line to set the word line to a logic low state following the first time period.

12. The memory circuit of claim 11, wherein the mimicked write driver device generates an activation signal based on a write enable signal.

13. The memory circuit of claim 11, wherein the first time period corresponds to an amount of time for a write driver circuit to set the bit line coupled to the memory cell to the ground voltage.

14. The memory circuit of claim 11, further comprising a multiplexor that selects between a write path and a read path for the memory circuit according to a write enable signal.

15. The memory circuit of claim 11, further comprising a plurality of parallel transistors having a capacitance that mimics a corresponding capacitance of the word line coupled to the memory cell.

16. The memory circuit of claim 15, further comprising an inverter chain that generates a deactivation signal for the word line driver device in response to a signal generated using the plurality of parallel transistors and an activation signal.

17. The memory circuit of claim 16, wherein a second amount of time to charge the plurality of parallel transistors and a delay time of the inverter chain corresponds to an assertion time of the word line to complete a write operation for the memory cell.

18. A method, comprising:
initiating a write operation for a memory cell;
generating a first delay signal corresponding to activation of a word line coupled to the memory cell; and
generating, using the first delay signal, a second delay signal corresponding to deactivation of the word line coupled to the memory cell.

19. The method of claim 18, wherein generating the first delay signal is responsive to a voltage of a mimicked bit line falling below a threshold.

20. The method of claim 18, further comprising asserting the word line in response to the first delay signal transitioning to a logic high state.
